(19) United States
(12) Patent Application Publication
(10) Pub. No.: US 2021/0273635 A1
(43) Pub. Date: Sep. 2, 2021

(54) DETERMINING AN OPERATING CONDITION OF A TRANSISTOR

(71) Applicant: Maschinenfabrik Reinhausen GmbH, Regensburg (DE)

(72) Inventor: Matthew Wilcock, Cambridge (GB)

(21) Appl. No.: 17/276,850

(22) PCT Filed: Sep. 19, 2019
(86) PCT No.: PCT/EP2019/075226

§ 371 Date: Mar. 17, 2021

(30) Foreign Application Priority Data
Sep. 21, 2018 (EP) 18196031.1

(51) Int. Cl. H03K 17/082

(52) U.S. Cl. CPC H03K 17/0828; H03K 2017/0806

(57) ABSTRACT

A power electronic system includes a transistor, a feedback device, and an evaluator. The feedback device is connected between a control terminal of the transistor and a collector terminal of the transistor. The feedback device is configured to provide a negative feedback to the transistor. The evaluator is configured to determine a junction temperature of the transistor or an on-state current of the transistor based upon on a control voltage of the transistor.

### CROSS-REFERENCE TO PRIOR APPLICATIONS

This application is a U.S. National Phase Application under 35 U.S.C. § 371 of International Application No. PCT/EP2019/075226, filed on Sep. 19, 2019, and claims benefit to European Patent Application No. EP 18196031.1, filed on Sep. 21, 2018. The International Application was published in English on Mar. 26, 2020 as WO 2020/058434 under PCT Article 21(2).

### FIELD

The present invention relates to a power electronic system with a transistor and to a method for determining an operating condition of a transistor.

### BACKGROUND

In power electronic systems, for example power converters, the junction temperature of power semiconductor devices is a critical quantity setting a limit on system operation. Exceeding an absolute limit may be regarded as catastrophic and thermal behavior throughout the lifetime of the system affects reliability and rate of degradation. Furthermore, high junction temperatures or high on-state currents may cause device failures, especially because the currents and voltages switches by means of power electronic systems may be very high. In power electronics systems, several power semiconductor devices may be connected in parallel to allow operation at the desired currents. Therefore, also distribution of on-state currents to parallel devices may be of interest.

Existing approaches to determine junction temperature may use on-chip sensing diodes. To determine the on-state current, an auxiliary emitter cell carrying a small proportion of the device current may be connected in series with a temperature sense resistor. In both cases, a hardware architecture of the power converter is complex and requires dedicated sensor elements.

### SUMMARY

In an embodiment, the present invention provides a power electronic system that includes a transistor, a feedback device, and an evaluator. The feedback device is connected between a control terminal of the transistor and a collector terminal of the transistor. The feedback device is configured to provide a negative feedback to the transistor. The evaluator is configured to determine a junction temperature of the transistor or an on-state current of the transistor based upon on a control voltage of the transistor.

### BRIEF DESCRIPTION OF THE DRAWINGS

Embodiments of the present invention will be described in even greater detail below based on the exemplary figures. The present invention is not limited to the exemplary embodiments. All features described and/or illustrated herein can be used alone or combined in different combinations in embodiments of the present invention. The features and advantages of various embodiments of the present invention will become apparent by reading the following detailed description with reference to the attached drawings which illustrate the following:

FIG. 1 shows a block diagram of an exemplary embodiment of a power electronic system according to the present invention; and

FIG. 2 shows a block diagram of a further exemplary embodiment of a power electronic system according to the present invention.

### DETAILED DESCRIPTION

Embodiments of the present invention provide an improved concept for determining an operating condition of a transistor of a power electronic system that allows for a simpler structure of the power electronic system.

The improved concept according to the present invention is based on the idea to prevent the transistor from reaching or staying in a saturation state, measuring a control voltage of the transistor and exploiting the fact that the control voltage represents a temperature-sensitive electrical parameter, TSEP, as well as a current-sensitive electrical parameter, CSEP, if the saturation state is avoided.

According to an embodiment of the present invention, a power electronic system is provided. The system comprises a transistor, in particular an insulated-gate bipolar transistor, IGBT, and a feedback device connected between a control terminal of the transistor and a collector terminal of the transistor for providing a negative feedback to the transistor. The system comprises an evaluation unit configured to determine a junction temperature of the transistor and/or an on-state current of the transistor depending on a control voltage, in particular a gate voltage, of the transistor.

If the feedback device is enabled, it provides the negative feedback to the transistor, in particular IGBT, in order to prevent the transistor from reaching a saturation state. In case the transistor is not in the saturation state, the feedback device is disabled. In cases where the transistor approaches or is in the saturation state, the feedback device is enabled resulting in a reduction of a gate-emitter voltage of the transistor. This causes the collector-emitter voltage to rise, depleting a MOS region of the transistor of excess carriers and thus greatly reducing a stored charge in a surrounding region. When the transistor is switched off from this state, that is while the feedback device is enabled, a switching speed may be significantly increased and switching loses may be significantly reduced. It is pointed out that the feedback device is not necessarily enabled in case the transistor approaches or is in saturation. Rather, it may be enabled only in specific cases.

According to several implementations, the feedback device is enabled before the transistor is turned off, in particular during a predefined period or at a predefined instance before the transistor is turned off, in particular several μs or several tens of μs, for example 5 μs to 50 μs, for example 5 μs to 15 μs, for example 10 μs, before the transistor is turned off.

In this way, the transistor is prevented from reaching the saturation state or driven out of the saturation state as described. Consequently, the control voltage of the transistor is a TSEP and a CSEP, which is not the case during saturation of the transistor.

Therefore, the on-state current and/or junction temperature may be determined in a particularly simple way, namely from the control or gate voltage, which is controlled anyway for the operation of the power electronic system.

The control voltage is in particular determined, for example measured or determined based on a measurement, while the negative feedback is provided, in particular while the feedback device is enabled.

According to several implementations of the power electronic system, the feedback device comprises at least one diode, for example exactly one diode or two or more diodes coupled in series to each other.

According to several implementations, the feedback device is enabled, if a voltage drop over the feedback device is greater than a threshold value, in particular a breakdown voltage or a forward threshold voltage of the at least one diode, and disabled otherwise.

According to several implementations, the at least one diode comprises a Schottky diode, a PN diode or a PIN diode.

According to several implementations, a cathode of the at least one diode is connected to the collector of the transistor directly or indirectly, that means without or with further electronic components in between, respectively.

According to several implementations, the power electronic system comprises a control element connected between the control terminal of the transistor and the feedback device, in particular to an anode of the at least one diode. The control element has a controllable resistance.

According to several implementations, the feedback device is enabled if the control element is turned on, in particular is conducting, in particular has a minimum resistance. The feedback device is disabled if the control element is turned off, in particular is not conducting, in particular has a maximum resistance.

According to several implementations, the control element comprises a further transistor, in particular a field effect transistor, FET, for example a MOSFET or a JFET.

According to several implementations, the power electronic system comprises a control unit for controlling a resistance of the control element, for example by controlling a control voltage of the further transistor.

According to several implementations, the evaluation unit is configured to determine the junction temperature of the transistor depending on the control voltage of the transistor and an on-state current of the transistor. The on-state current may be measured directly or indirectly and may for example be predetermined.

According to several implementations, the evaluation unit is configured to determine the on-state current of the transistor depending on the control voltage of the transistor and the junction temperature of the transistor. Such implementations use a predetermined value for the junction temperature. The junction temperature may for example be predetermined or may be estimated based on a thermal model or based on one or more TSEPs apart from the on-state voltage or may be obtained from a look-up table.

One advantage of such implementations is that an appropriate turn-off gate resistor for the transistor may be selected based on the determined on-state voltage.

According to several implementations, the on-state current is given by Iₒₙ=K*(V_{c}−V_{T})\hat{ }2, wherein Iₒₙ is the on-state current, V_{c} is the control voltage, V_{T} is a threshold voltage, in particular gate threshold voltage, and K is a factor incorporating for example a conductance of the transistor, in particular a MOS part of the transistor. The gate voltage V_{T} and the factor K both depend on the junction temperature.

According to several implementations, the evaluation unit is configured to determine the on-state current of the transistor and the junction temperature of the transistor depending on the control voltage of the transistor and an on-state voltage of the transistor. The on-state voltage may be measured directly or indirectly, in particular while the feedback device is disabled, for example before the feedback device is enabled.

In such implementations, knowing the on-state voltage allows to exploit both the control voltage and, with the feedback device disabled, the on-state voltage being a TSEP and a CSEP at the same time. In addition to the advantages described above, this is particularly valuable for validating a current sharing and a thermal management of the transistor and further power semiconductor devices coupled in parallel to the transistor.

According to several implementations, the system comprises a drive unit configured to control a switching behavior of the transistor, in particular to turn the transistor on or off.

According to several implementations, the drive unit is configured to turn the transistor off while the feedback device is enabled, in particular, after the feedback device is enabled.

According to several implementations, the system comprises a delay element, in particular a programmable delay element coupled to the drive and the control unit. The delay element is configured to delay turning off the transistor with respect to enabling the feedback device.

According to several implementations, the delay lies in the order of several μs or several tens of μs, for example in the range of 5 μs to 50 μs, for example in the range of 5 μs to 15 μs, for example 10 μs.

According to several implementations, the drive unit may comprise the control unit.

According to several implementations, the drive unit may comprise the feedback device.

According to several implementations, the power electronic system comprises a power converter, the power converter comprising the transistor as a switching element for an operation of the power converter.

According to several implementations, the evaluation unit is arranged separately from the power converter. Alternatively, the evaluation unit may be comprised by the power converter.

According to an embodiment of the present invention, a method for determining an operating condition of a transistor of a power electronic system is provided. According to the method, a negative feedback is provided to the transistor to prevent the transistor from reaching a saturation state or from staying in the saturation state. A control voltage of the transistor is measured while the negative feedback is provided, in particular while the feedback device is enabled. The operating condition, in particular including a junction temperature of the transistor and/or an on-state current of the transistor, is determined depending on the control voltage.

According to some implementations of the method, the junction temperature is determined depending on a control voltage and on a predetermined value for the on-state current.

According to some implementations of the method, the on-state current is determined depending on the control voltage and a predetermined value for the junction temperature.

According to some implementations of the method, an on-state voltage of the transistor is measured while the negative feedback is not provided, in particular while the feedback device is disabled. The junction temperature and/or the on-state current is determined depending on the control voltage and the on-state voltage.

Further implementations of the method according to the improved concept follow readily from the various implementations and embodiments of the power electronic system according to the improved concept and vice versa. In particular, individual or several components or arrangements described with respect to the system may be implemented accordingly for performing the method according to the improved system.

In the following, the invention is explained with respect to exemplary implementations by reference to the drawings. Components that are functionally identical or have an identical effect may be denoted by identical reference signs. Identical components or components with identical functions or effects may be described only with respect to the figure where they occur first. Their description is not necessarily repeated in subsequent figures.

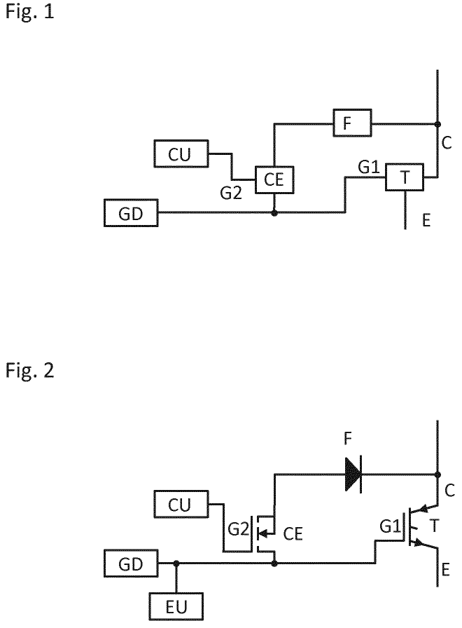

FIG. 1 shows a block diagram of an exemplary embodiment of a power electronic system according to the present invention. The system comprises a transistor T and a feedback device F connected between a collector terminal C and a control terminal G1 of the transistor T. The transistor T may for example be comprised by a power converter.

Depending on the type of the transistor T, the system may or may not comprise a control element CE connected between the feedback device F and the control terminal G1 of the transistor T. The system may then comprise a control unit CU connected to a control terminal G2 of the control element CE for controlling a resistance of the control element CE.

Optionally, the system may comprise a drive unit GD for controlling a control voltage applied to the control terminal G1 of the transistor T. The drive unit GD may comprise an evaluation unit configured to receive a control voltage applied at the gate G1 of the transistor T. Alternatively, the evaluation unit may be implemented separately from the drive unit GD.

FIG. 2 shows a block diagram of a further exemplary embodiment of a power electronic system according to the present invention. The embodiment of FIG. 2 is based on the embodiment of FIG. 1, wherein the control element CE comprises a MOSFET (the circuit symbol for an n-channel enrichment type MOSFET is chosen merely as a non-limiting example), the feedback device F comprises a diode and the transistor T comprises an IGBT (the circuit symbol for an n-channel depletion type IGBT is chosen merely as a non-limiting example). Consequently, the control terminals G1, G2 are gate terminals G1, G2 and the control voltages of the transistor T and the control element CE are respective gate voltages. The embodiment of FIG. 2 may comprise an evaluation unit EU connected to receive a gate voltage applied at the gate terminal G1 of the transistor T.

The operation of a system according to an embodiment of the present invention is described in the following with respect to FIG. 2. However, the embodiments of FIG. 1 operate in an analogous way.

During operation of the power converter, the drive unit GD may control switching of the transistor T, that is turning the transistor T on or off, according to a switching scheme of the power converter by controlling a gate voltage at the gate G1 of the transistor T.

To reduce excess charges in a MOS region of the transistor T, the feedback device F is utilized to prevent the transistor T from reaching a saturation state of the transistor T or driving the transistor T out of the saturation state.

To this end, the control unit CU may apply or change the gate voltage at the gate G2 of the control element CE in order to reduce the resistance of the control element CE, that is to turn the control element CE on. Therefore, a gate-emitter voltage of the transistor T is reduced and a collector-emitter voltage of the transistor T rises, depleting a MOS region of the transistor T of excess carriers.

By reducing the excess carriers, the gate voltage of the transistor T is temperature sensitive as well as sensitive to an on-state current of the transistor T.

The evaluation unit EU is configured to determine a junction temperature of the transistor T or the on-state current of the transistor T depending on the gate voltage at the gate terminal G1 of the transistor T.

In particular, the evaluation unit EU may use a measured value of the gate voltage at the gate terminal G1 and a predetermined value of the on-state current to determine the junction temperature. In addition or alternatively, the evaluation unit EU may use a measured value of the gate voltage at the gate terminal G1 and a predetermined value of the junction temperature to determine the on-state current. In addition or alternatively, the evaluation unit EU may be configured and connected to receive an on-state voltage, in particular emitter-collector voltage, of the transistor T and to use respective measured values of the gate voltage at the gate terminal G1 and the on-state voltage to determine the determine the junction temperature and the on-state current.

By means of a power electronic system or method according to the improved concept, junction temperature and/or on-state current of a power transistor may be determined with a particularly simple setup. In addition, the switching losses of the transistor may be reduced. To achieve this, neither modification of the transistor nor a complex gate drive is required. The improved concept or certain aspects of it may have valuable uses with semiconductor devices not described herein, for example devices based on silicon carbide.

While embodiments of the invention have been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### REFERENCE SIGNS

T transistor
G1, G2 control terminals
C collector terminal
E emitter terminal
F feedback device
CE control element
CU control unit
GD drive unit

1: A power electronic system comprising:
a transistor;
a feedback device connected between a control terminal of the transistor and a collector terminal of the transistor, the feedback device being configured to provide a negative feedback to the transistor; and
an evaluator configured to determine a junction temperature of the transistor or an on-state current of the transistor based upon on a control voltage of the transistor.

2: The power electronic system according to claim 1, wherein the transistor is an insulated-gate bipolar transistor (IGBT).

3: The power electronic system according to claim 1, wherein the feedback device comprises at least one diode.

4: The power electronic system according to claim 3, wherein a cathode of the at least one diode is connected to the collector terminal of the transistor directly or indirectly.

5: The power electronic system according to claim 1, further comprising a control element connected between the control terminal of the transistor and the feedback device, the control element having a controllable resistance.

6: The power electronic system according to claim 5, wherein the control element comprises a further transistor.

7: The power electronic system according to claim 5, further comprising a controller configured to control a resistance of the control element.

8: The power electronic system according to claim 1, wherein the evaluator is configured to determine the junction temperature of the transistor based upon on the control voltage of the transistor and the on-state current of the transistor.

9: The power electronic system according to claim 1, wherein the evaluation unit is configured to determine the on-state current of the transistor depending on the control voltage of the transistor and the junction temperature of the transistor.

10: The power electronic system according to claim 1, wherein the evaluator is configured to determine the on-state current of the transistor and the junction temperature of the transistor depending on the control voltage of the transistor and the on-state voltage of the transistor.

11: The power electronic system according to claim 1 comprising a power converter, the power converter comprising the transistor configured as a switching element for an operation of the power converter.

12: A method for determining an operating condition of a transistor of a power electronic system, the method comprising:
providing a negative feedback to the transistor-, the negative feedback being configured from reaching a saturation state or from staying in the saturation state;
measuring a control voltage of the transistor while the negative feedback is provided; and
determining a junction temperature of the transistor or an on-state current of the transistor depending on the measured control voltage.

13: The method according to claim 12, wherein the junction temperature is determined depending on the control voltage and a predetermined value for the on-state current.

14: The method according to claim 12, wherein the on-state current is determined depending on the control voltage and a predetermined value for the junction temperature.

15: The method according to claim 12, further comprising:
measuring the on-state voltage of the transistor while the negative feedback is not provided; and
determining the junction temperature or the on-state current depending on the control voltage and the on-state voltage.

16: The power electronic system according to claim 6, wherein the further transistor is a field effect transistor, FET.
